(19) United States
(12) Patent Application Publication
(10) Pub. No.: US 2020/0044184 A1
(43) Pub. Date: Feb. 6, 2020

(54) ORGANIC LIGHT-EMITTING DEVICE

(71) Applicant: Yungu (Gu'an) Technology Co., Ltd., Langfang (CN)

(72) Inventor: Kang WAN, Langfang (CN)

(21) Appl. No.: 16/600,603

(22) Filed: Oct. 14, 2019

Related U.S. Application Data
(63) Continuation of application No. PCT/CN2018/092299, filed on Jun. 22, 2018.

(30) Foreign Application Priority Data
Dec. 29, 2017 (CN) 201721917719.7

(51) Int. Cl. H01L 51/52; H01L 51/00

(52) U.S. Cl. CPC H01L 51/5237; H01L 51/0097; H01L 51/5221

(57) ABSTRACT

An organic light-emitting device includes: a substrate, a display driving layer, a display light emitting layer and an encapsulation layer, which are sequentially overlaid. The display light-emitting layer includes a plurality of functional film layers, and at least one of the functional film layers includes at least one uneven stress release region.

### CROSS-REFERENCE TO RELATED APPLICATIONS

This application is a continuation of International Application No. PCT/CN2018/092299 filed on Jun. 22, 2018, which claims priority to Chinese patent application No. 201721917719.7 filed on Dec. 29, 2017. Both applications are incorporated herein by reference in their entireties.

### TECHNICAL FIELD

The disclosed embodiments relate to the field of display technologies, and particularly to an organic light-emitting device.

### BACKGROUND

An Organic Light-Emitting Diode (OLED) device is considered to be the most promising planar display device, and is the most possibility to be manufactured as a flexible display device. However, the problem of a short lifetime of the OLED device restricts its industrialization. Referring to FIG. 1a, when an organic light-emitting device is bent, a stress concentration will be caused in the bend region, which will cause a first film layer 001 to be broken. Referring to FIG. 1b, when the organic-light emitting device is bent, a stress concentration will be caused in the bend region, which will cause defects such as stripping or bubbling between the first film layer 001 and a second film layer 002. In particular, the adhesion between a cathode and an organic light-emitting layer of the organic light-emitting device is less than the adhesion between an encapsulation layer and the cathode. Therefore, when the organic light-emitting device is bent, it is easy to cause the cathode electrode layer and the organic light-emitting layer to be peeled off, which leads to a failure of the display.

### SUMMARY

In view of this, embodiments of the present application provide an organic light-emitting device, which solves problems such as peeling, breaking and bubbling between film layers due to the bending of a flexible display screen.

An embodiment of the present application provides an organic light-emitting device which includes: a substrate, a display driving layer, a display light-emitting layer and an encapsulation layer. The substrate, the display driving layer, the display light-emitting layer and the encapsulation layer are sequentially overlaid. The display light-emitting layer includes a plurality of functional film layers, and at least one of the functional film layers includes at least one uneven stress release region.

In an embodiment of the present application, the stress release region is located in a pre-bending region of the organic light-emitting device.

In an embodiment of the present application, the display light-emitting layer includes a plurality of the stress release region, and the stress release regions are overlaid.

In an embodiment of the present application, the display light-emitting layer includes a plurality of the stress release regions, and the stress release regions have a same cross-sectional shape.

In an embodiment of the present application, the cross-sectional shape of the plurality of stress release regions comprises any one or any combination of a concave curved shape, a convex curved shape, a wavy shape and a saw tooth shape.

In an embodiment of the present application, the functional film layers of the display light-emitting layer includes : a planarization layer, an anode electrode layer, an organic light-emitting layer and a cathode electrode layer, which are sequentially overlaid.

In an embodiment of the present application, at least one of the planarization layer, the anode electrode layer, the organic light emitting layer, and the cathode electrode layer includes at least one of the stress release regions.

In an embodiment of the present application, the encapsulation layer includes an inorganic layer and an organic layer, both of which are overlaid, the inorganic layer is located between the display light-emitting layer and the organic layer, and the inorganic layer includes at least one uneven stress release region.

In an embodiment of the present application, the stress release region of the inorganic layer is overlaid on the stress release region of the functional film layers of the display light-emitting layer.

In an embodiment of the present application, the cross-sectional shape of the stress release region of the inorganic layer is the same as the cross-sectional shape of the stress release region of the display light-emitting layer.

In an embodiment of the present application, the display driving layer is a Thin Film Transistor (TFT) backplane layer.

In an organic light-emitting device provided by an embodiment of the present application, at least one uneven stress release region is prepared on at least one functional film layer of the organic light-emitting layer. The bending stress caused during bending process of the organic light-emitting device can be released by the uneven shape of the stress release region, thus the bending stress of the at least one functional film layer can be relieved, so that cracks caused by the bending stress of the at least one functional film layer are effectively prevented, defects such as peeling off, bubbling and so on occurred between the at least one functional film layer and other functional film layers are also effectively prevented, and the reliable performance of the organic light-emitting device can be improved.

### BRIEF DESCRIPTION OF DRAWINGS

FIG. 1a is a diagram showing bending failure between film layers of a conventional organic light emitting device.

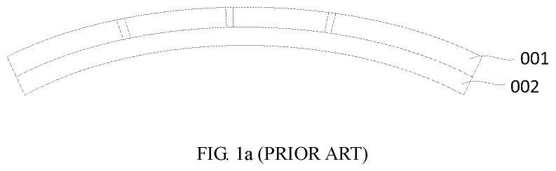

FIG. 1b is a diagram showing bending failure between film layers of another conventional organic light emitting device.

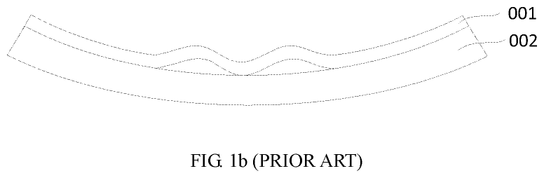

FIG. 2 is a schematic structural diagram of an organic light emitting device according to an embodiment of the present application.

FIG. 3 is a schematic structural diagram of a display light emitting layer of an organic light emitting device according to an embodiment of the present application.

FIG. 4 is a schematic structural diagram of an organic light emitting device according to another embodiment of the present application.

### DETAILED DESCRIPTION

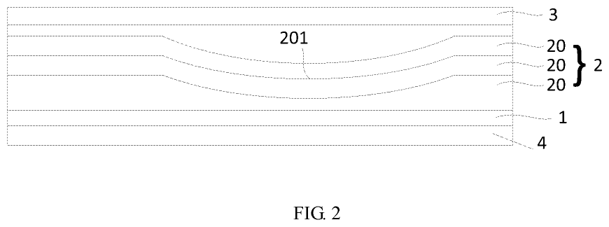

FIG. 2 is a schematic structural diagram of an organic light-emitting device according to an embodiment of the present application.

As shown in FIG. 2, the organic light-emitting device includes a substrate 4, a display driving layer 1, a display light-emitting layer 2 and an encapsulation layer 3, which are sequentially overlaid.

The substrate 4 may be a flexible substrate, such as a polyimide (PI) substrate; the substrate 4 may be a rigid substrate, such as a glass substrate. The type of the substrate 4 is not specifically limited in the embodiments of the present application. The substrate 4 is provided to make the preparation of the display driving layer 1, the display light emitting layer 2 and the encapsulation layer 3 facilitate.

The display driving layer 1 is used to drive the display light-emitting layer 2 to emit light. For example, when the display light-emitting layer 2 emits light and what color light is emitted or the like is controlled by an external drive circuit through the display driver layer 1.

The encapsulation layer 3 is mainly used to prevent water vapor and oxygen from entering into the organic light emitting device, and to prevent aging of the organic light emitting device, thereby the lifetime of the organic light emitting device is extended. In an embodiment of the present application, the encapsulation layer 3 may be realized by Thin Film Encapsulation (TFE).

In an embodiment of the present application, the display light-emitting layer 2 may include a plurality of functional film layers 20, and the display light-emitting layer 2 emits light by the interaction of the plurality of functional film layers 20. Among the plurality of functional film layers 20 of the display light emitting layer 2, at least one of the functional film layers 20 includes at least one uneven stress release region 201.

An embodiment of the present application provides an organic light-emitting device, the at least one uneven stress release region 201 is set up on the at least one functional film layer 20 of the display light emitting layer 2. The uneven structure of the stress release region 201 can release bending stress caused by the bending of the organic light-emitting device, thus the bending stress of the at least one functional film layer 20 is alleviated. So that cracks caused by the bending stress of the at least one functional film layer 20 are effectively prevented, and defects such as peeling off, bubbling and so on occurred between the at least one functional film layer 20 and other functional film layers 20 are also effectively prevented, and the reliable performance of the organic light-emitting device can be improved.

The uneven structure of the stress release region 201 may be located in an uneven surface region of the functional film layers 20. In one embodiment, the cross-sectional shape of the stress release structure of the stress release region 201 comprises any one or any combination of an arc that is convex toward the encapsulation layer 3, an arc that is concave toward the substrate 4, a wavy shape and a saw tooth shape. The detailed shape of the stress release region 201 may be designed and adjusted depending on the bending mode to be achieved. However, the shape of stress release region 201 is not specifically limited in the embodiments of the present application.

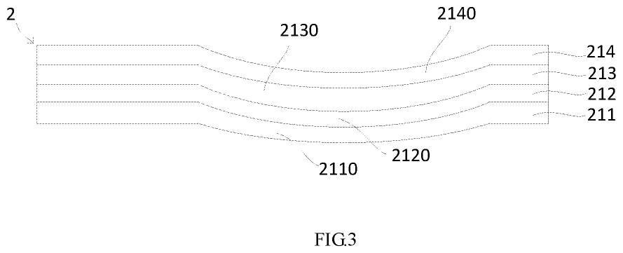

FIG. 3 is a schematic structural diagram of a display light emitting layer of an organic light-emitting device according to an embodiment of the present application.

As shown in FIG. 3, in an embodiment, the display light emitting layer 2 includes a planarization layer 211, an anode electrode layer 212, an organic light emitting layer 213 and a cathode electrode layer 214, which are sequentially overlaid. The planarization layer 211 is generally made of an organic material, the tensile and the extensibility of the organic material are better, so that a planarization surface is easily prepared on the display driving layer 1. The anode electrode layer 212 is prepared on the planarization layer 211, and the flat surface formed by the planarization layer 211 makes it facilitate to prepare the anode electrode layer 212. The organic light-emitting layer 213 is prepared between the anode electrode layer 212 and the cathode electrode layer 214. When a voltage is applied to the organic light-emitting device, the hole output by the anode electrode layer 212 is combined with the electron output by the cathode electrode layer 214 at the organic light-emitting layer 213, so that the organic light-emitting device can emit light, and the light emitted by the organic light-emitting device can be emitted through the anode electrode layer 212 or the cathode electrode layer 214. However, the display light-emitting layer 2 may have other structures, as long as the light-emitting requirements of the organic light-emitting device can be satisfied, and the structure of the display light-emitting layer 2 is not specifically limited in the embodiments of the present application.

In an embodiment, the planarization layer 211 may include at least one uneven first stress release region 2110, the first stress release region 2110 may be prepared by an exposure patterning process. When the planarization layer 211 includes the first stress release region 2110, the length of the anode electrode layer 212 can be increased, thereby the contact area between the anode electrode layer 212 and the planarization layer 211 is increased. The bending stress caused in the bending process of the organic light-emitting device can be released by the uneven structure of the first stress release region 2110, thereby it can be prevented that the anode electrode layer 212 is peeled off the planarization layer 211.

In an embodiment, the anode electrode layer 212 includes at least one uneven second stress release region 2120, the second stress release region 2120 may be prepared by a wet etching process (or a convex structure of the anode electrode layer 212 is prepared when the planarization layer 211 is exposed), the process preparation process is simple. When the anode electrode layer 212 includes the second stress release region 2120, the contact area between the anode electrode layer 212 and the planarization layer 211 can be increased. When the organic light-emitting device is bent, the bending stress generated during the bending of the organic light-emitting device can be released by the uneven structure of the second stress release region 2120, thereby the anode electrode layer 212 is prevented from being peeled off.

Furthermore, in an embodiment, in order to release the stress between the film layers, the organic light-emitting layer 213 may also include at least one uneven third stress release region 2130, and the cathode electrode layer 214 may also include at least one uneven fourth stress release region 2140, the bending stress generated during the bending of the organic light-emitting device can be released by the uneven structure of the third stress release region 2130 or the fourth stress release region 2140, thereby the anode electrode layer 212 or the cathode electrode layer 214 can be prevented from being peeled off.

I n the planarization layer 211, the anode electrode layer 212, the organic light emitting layer 213 and the cathode electrode layer 214 which are used as the functional film layer 20 included in the display light emitting layer 2, only one of the above layers may include the stress release region 201, for example, the planarization layer 211 includes the first stress release region 2110, or the anode electrode layer 212 includes the second stress release region 2120, or the organic light emitting layer 213 may include the third stress release region 2130, or and the cathode electrode layer 214 may include the fourth stress release region 2140. It can also be that plurality of the functional film layers 20 includes the stress release region 201 respectively. Which one of the functional film layers 20 or which layers of the functional film layers 20 in the display light-emitting layer 2 include the stress release region 201 is not specifically limited in the embodiments of the present application. When each of the functional film layers 20 of the display light-emitting layer 2 includes the stress release region 201, the overall bending resistance of the organic light-emitting device can be further improved.

In an embodiment, the first stress release region 2110, the second stress release region 2120, the third stress release region 2130 and the fourth stress release region 2140 are overlaid. In this way, the bending stress at a corresponding superposition position can be released well by the superposition of the plurality of stress release region 201. In an embodiment, the plurality of stress release region 201 overlaid correspondingly may be prepared in a pre-bending region of the organic light-emitting device.

In another embodiment, the planarization layer 211 may be a flat structure, and the first stress release region 2110 may not be included in the planarization layer 211. The second stress release region 2120, the third stress release region 2130, and the fourth stress release region 2140 are overlaid. In this way, the bending stress at the corresponding superposition position can also be released well. In an embodiment, the plurality of stress release region 201 overlaid correspondingly can be prepared in the pre-bending region of the organic light-emitting device.

In the embodiments of the present application, according to different design positions of the pre-bending regions of the organic light-emitting device and different bending requirements of the different functional film layers 20, the stress release region 201 of any two or several functional film layers 20 of the display light-emitting layer 2 may be overlaid, and the corresponding overlaid positions may be different. The stress release regions 201 of which ones of the several functional film layers 20 of the display light-emitting layer 2 are overlaid is not specifically limited in the embodiments of the present application, and the detail positions where the stress release regions 201 overlaid correspondingly are not specifically limited in the embodiments of the present application.

In an embodiment, the shapes of the first stress release region 2110, the second stress release region 2120, the third stress release region 2130 and the fourth stress release region 2140, which are overlaid in the organic light-emitting device, are the same; or the shapes of the second stress release region 2120, the third stress release region 2130 and the fourth stress release region 2140, which are overlaid correspondingly in the organic light-emitting device, are the same. When the shapes of the plurality of stress release region 201, which are overlaid correspondingly, are the same, after the lowest stress release region 201 is prepared, the other functional film layers 20 above the lowermost stress release region 201 can be directly overlaid and prepared in the corresponding position by copying the shape of the lowermost stress release region 201, so that it is not necessary to prepare the stress release region 201 of the other functional film layers 20 above by special graphical processes, thereby the preparation process is further simplified. The shape of any two or more stress release regions 201 overlaid in the organic light-emitting device may be the same. Which stress release regions 201 superimposed correspondingly have the same shape are not specifically limited in the embodiments of the present application.

Although in the embodiments and the drawings of the present application, the shapes of the plurality of stress release regions 201 are the same, and the plurality of stress release regions 201 are overlaid correspondingly in the organic light-emitting device, the shapes of the plurality of stress release regions 201 may be different or not exactly the same, and the plurality of stress release regions 201 may also not be superimposed correspondingly in the organic light-emitting device. The shapes and the detailed locations of the plurality of stress release regions 201 can be flexibly selected according to actual production requirements.

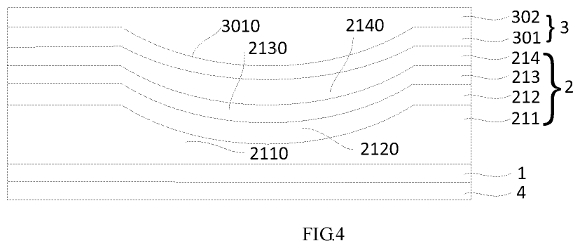

FIG. 4 is a schematic structural diagram of an organic light-emitting device according to another embodiment of the present application.

As shown in FIG. 4, the encapsulation layer 3 may be a multi-layer stack structure of an inorganic layer 301 and an organic layer 302. The inorganic layer 301 is used for blocking water and oxygen, and the organic layer 302 is used for planarization. In an embodiment, the encapsulation layer 3 includes the inorganic layer 301 and the organic layer 302 that are overlaid. The inorganic layer 301 is located between the display light-emitting layer 2 and the organic layer 302. The water and oxygen can be effectively prevented from eroding the display light-emitting layer 2 by preparing the inorganic layer 301 and the organic layer 302 in the encapsulation layer 3, and the planarization of the surface of the organic light-emitting device can also be ensured.

In an embodiment, the inorganic layer 301 includes at least one uneven fifth stress release region 3010, and when the organic light-emitting device is bent, the bending stress caused during the bending of the organic light-emitting device can be released by the uneven shape of the fifth stress release region 3010, and it can be prevented that the inorganic layer 301 is peeled off the display light emitting layer 2.

In an embodiment, the fifth stress release region 3010 is overlaid on the stress release regions 201 of the functional film layers 20 on the surface of the display driving layer 1, so that the fifth stress release region 3010 will be conveniently prepared, for example, the fifth stress release region 3010 may be prepared in the pre-bending region of the organic light-emitting device.

In an embodiment, the shape of the fifth stress release region 3010 is the same as that of the stress release region 201 of the functional film layers 20 on the surface of the driving layer 1. In this case, after the stress release region 201 of the functional film layers 20 on the surface of the driving layer 1 is prepared, the above inorganic layer 301 can be directly overlaid and prepared in the corresponding position, by copying the shape of the stress release region 201 of the functional film layers 20 on the surface of the driving layer 1, so that it is not necessary to prepare the stress release region 201 of the inorganic layer 301 by special graphical processes, thereby the preparation process will be further simplified.

Whether the fifth stress release region 3010 is correspondingly superimposed with the stress release region 201 of the functional film layers 20 on the surface of the display driving layer 1, and whether the shape of the fifth stress release region 3010 is the same as that of the stress release region 201 are not specifically limited in the embodiments of the present application.

As shown in FIG. 4, in an embodiment, the display driving layer 1 may be a Thin Film Transistor (TFT) backplane layer, the TFT backplane layer has the advantages of high responsiveness, high contrast, light, thin, low power consumption and so on, therefore, it is widely used in the display driving layer 1 of the organic light-emitting device for driving light emission of the display light-emitting layer 2. The detailed structure of the display drive layer 1 is not specifically limited in the embodiments of the present application.

The above description is only the preferred embodiment of the present application, and it is not to limit the present application. Any modifications, equivalent substitutions, or the like made within the spirit and principles of the present application shall fall within the protection scope of the present application.

What is claimed is:

1. An organic light-emitting device, comprising:
a substrate, a display driving layer, a display light-emitting layer and an encapsulation layer, which are sequentially overlaid,
wherein the display light-emitting layer comprises a plurality of functional film layers, and at least one of the functional film layers comprises at least one stress release region which is uneven.

2. The organic light-emitting device of claim 1, wherein the stress release region is located in a pre-bending region of the organic light-emitting device.

3. The organic light-emitting device of claim 1, wherein the display light-emitting layer comprises a plurality of the stress release regions, the stress release regions being overlaid.

4. The organic light-emitting device of claim 1, wherein the display light-emitting layer comprises the plurality of stress release regions having a same cross-sectional shape.

5. The organic light-emitting device of claim 4, wherein the cross-sectional shape of the plurality of stress release regions comprises any one or any combination of a concave curved shape, a convex curved shape, a wavy shape and a saw tooth shape.

6. The organic light-emitting device of claim 1, wherein the following functional film layers of the display light-emitting layer comprises: a planarization layer, an anode electrode layer, an organic light-emitting layer and a cathode electrode layer, which are sequentially overlaid.

7. The organic light-emitting device of claim 6, wherein at least one of the planarization layer, the anode electrode layer, the organic light emitting layer and the cathode electrode layer comprises at least one of the stress release regions.

8. The organic light-emitting device of claim 1, wherein the encapsulation layer comprises an inorganic layer and an organic layer, which are overlaid, the inorganic layer is located between the display light-emitting layer and the organic layer, and the inorganic layer comprises at least one stress release region which is uneven.

9. The organic light-emitting device of claim 8, wherein the stress release region of the inorganic layer is overlaid on the stress release region of the functional film layers of the display light-emitting layer.

10. The organic light-emitting device of claim 8, wherein the cross-sectional shape of the stress release region of the inorganic layer is the same as the cross-sectional shape of the stress release region of the display light-emitting layer.
